(19) United States
(12) Patent Application Publication
(10) Pub. No.: US 2013/0100619 A1
(43) Pub. Date: Apr. 25, 2013

(54) BRACING STRUCTURE FOR EXPANSION CARDS OF DIFFERENT SIZES AND ELECTRONIC DEVICE HAVING THE BRACING STRUCTURE

(71) Applicant: CHEN-LU FAN, Tu-Cheng (TW)

(72) Inventor: CHEN-LU FAN, Tu-Cheng (TW)

(73) Assignee: HON HAI PRECISION INDUSTRY CO., LTD., Tu-Cheng (TW)

(21) Appl. No.: 13/531,591

(22) Filed: Jun. 25, 2012

(30) Foreign Application Priority Data
Oct. 19, 2011 (TW) 100137816

(51) Int. Cl. H05K 5/02

(52) U.S. Cl. 361/752

(57) ABSTRACT

An exemplary bracing structure is provided for selectively securing either one expansion card or two expansion cards, all the expansion cards selected from a group consisting of differently sized expansion cards. The bracing structure includes a main body and a fixing frame. The main body has a fixing end. The fixing frame is configured for fixing one end of a selected one expansion card in position in the bracing structure. The fixing frame is detachably fixable to different positions on the main body according to the selected one expansion card. In two of the different positions, the fixing frame maintains different distances from the fixing end.

### BACKGROUND

1. Technical Field

The disclosure generally relates to electronic devices, and more particularly to an electronic device having a bracing structure for securing any of differently sized expansion cards.

2. Description of Related Art

Nowadays expansion cards which follow the Industry Standard Architecture (ISA) bus or Peripheral Component Interconnect (PCI) bus are commonly used in electronic devices such as servers, storages and printers, to expand the functions of the electronic devices. However, these expansion cards have different sizes. Taking a typical printer as an example, there are three types of expansion cards employed in the printer: a Full Height/Full Length Card (“FH/FL card” for short) which has a full height and a full length, a Full Height/Half Length Card (“FH/HL card” for short) which has a full height and a half length, and a Low Profile Card (“LP card” for short) which has a half height and a half length. Because of the different sizes of the expansion cards, it is necessary to provide different bracing structures for each expansion card, such as a larger bracing structure for the FH/FL card and a smaller bracing structure for the LP card and the FH/HL card. Typically, both these types of bracing structures need to be accommodated in the printer to obtain the multiple functions of the printer. However, disposing different bracing structures appropriate to different expansion cards not only occupies a lot of space inside the printer, but may also adversely influence other components inside the printer. For example, access to the other components inside the printer may be restricted.

What is needed, therefore, is a bracing structure for conveniently securing any of different expansion cards therein. What is also needed is an electronic device having such a bracing structure.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is an isometric, assembled view of a bracing structure securing an FH/FL card therein, in accordance with a first embodiment of the present disclosure.

FIG. 2 is an exploded isometric view of the bracing structure and FH/FL card of FIG. 1.

FIG. 3 shows another aspect of the parts of FIG. 2.

FIG. 4 is an isometric, assembled view of the bracing structure of FIG. 1 securing two FH/HL cards therein, in accordance with a second embodiment of the present disclosure.

FIG. 5 is a partly exploded, isometric view of the bracing structure and FH/HL cards of FIG. 4.

FIG. 6 is an isometric, assembled view of the bracing structure of FIG. 1 securing an FH/HL card and an LP card therein, in accordance with a third embodiment of the present disclosure.

FIG. 7 is a partly exploded, isometric view of the bracing structure and FH/HL and LP cards of FIG. 6.

### DETAILED DESCRIPTION

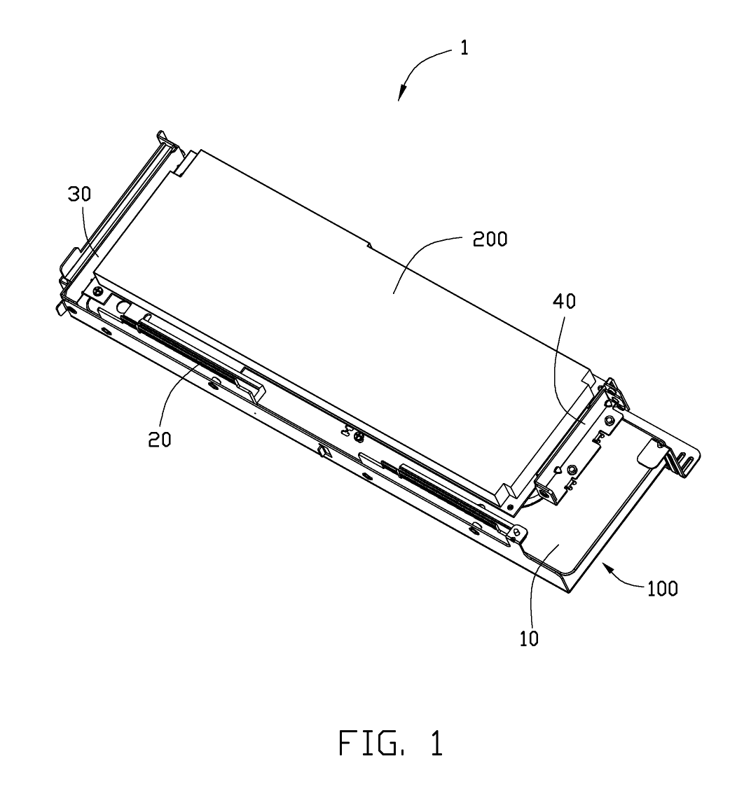

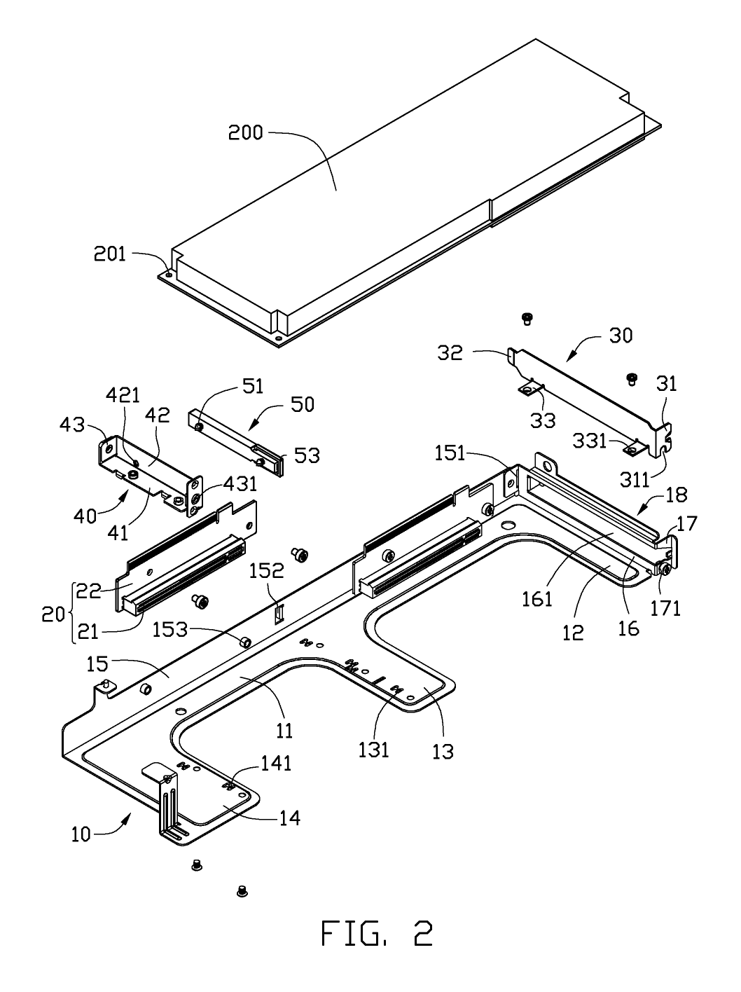

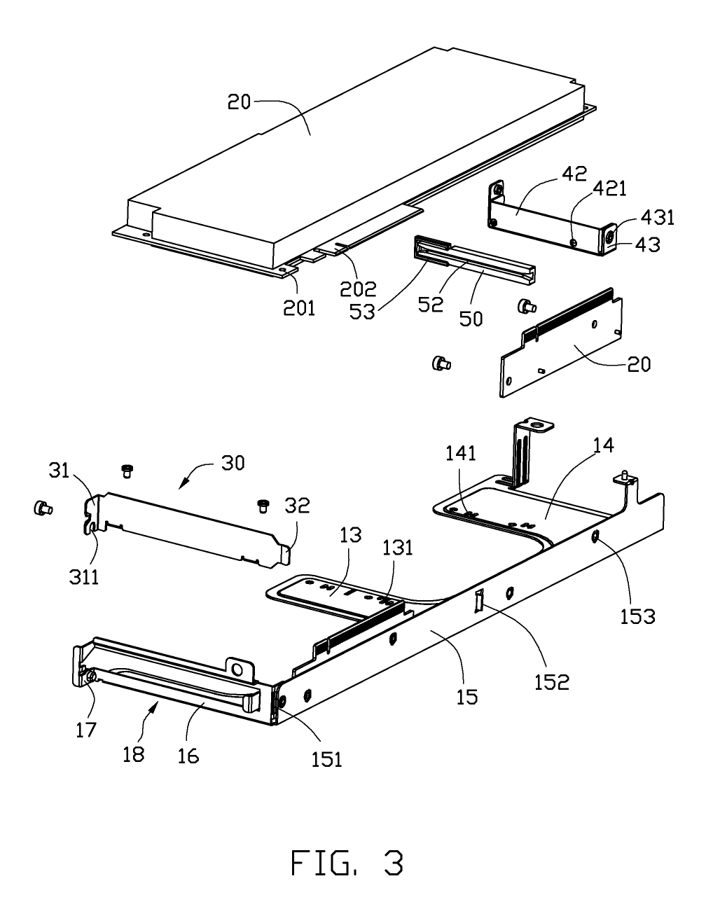

Referring to FIGS. 1-3, an electronic device 1 in accordance with a first embodiment is shown. The electronic device 1 includes a bracing structure 100, which secures an FH/FL card 200 therein. The bracing structure 100 includes a main body 10, two interface converters 20, a fixing board 30, a fixing frame 40, and a guiding element 50. The electronic device 1 can be for example a server, a storage or a printer. The bracing structure 100 mounted in the electronic device 1 is used for securing one or more PCI expansion cards, such as the FH/FL card 200 of the first embodiment. The FH/FL card 200 is fixed in the bracing structure 100 by the fixing board 30, one of the interface converters 20 and the fixing frame 40. In the embodiment illustrated in FIG. 1, it is a left one of the interface converters 20 which is used for such fixing.

The FH/FL card 200 has substantially a rectangular construction, and the fixing board 30 is employed to assist the bracing structure 100 in securing the FH/FL card 200. A length of the FH/FL card 200 is smaller than that of the main body 10. Four fixing holes 201 are defined at four corners of the FH/FL card 200, and a connecting foot 202 extends from a long lateral side of the FH/FL card 200. The fixing board 30 is fixed on a short side (hereinafter, “first end”) of the FH/FL card 200. That is, the fixing board 30 extends along a widthwise direction of the FH/FL card 200.

The main body 10 includes a long board 11, a first short board 12, a second short board 13, a third short board 14, a long vertical board 15, a short vertical board 16, and a blocking sheet 17. The first short board 12, the second short board 13 and the third short board 14 each extend perpendicularly inward from a long inner edge of the long board 11. The first, second and third short boards 12, 13, 14 are arranged in that sequence along the lengthwise direction of the long board 11. The long vertical board 15 bends vertically up from a long outer edge of the long board 11 far away from the three short boards 12, 13, 14. The short vertical board 16 bends vertically up from an end of the long board 11 and an outer edge of the first short board 12 far away from the second short board 13. The blocking sheet 17 bends perpendicularly outward from one end of the short vertical board 16 far away from the long vertical board 15. The short vertical board 16 and the blocking sheet 17 cooperatively form a fixing end 18 of the main body 10.

The second short board 13 is located between the first short board 12 and the third short board 14. The three short boards 12, 13, 14 and the long board 11 cooperatively form an approximately E-shaped construction. Alternatively, the main body 10 can be an elongate plate or have another desired shape according to actual requirements. A plurality of connecting holes 131, 141 are defined in the second short board 13 and the third short board 14, respectively, to connect the fixing frame 40 to the main body 10 at either the second short board 13 or the third short board 14, as selected.

The other end of the short vertical board 16 far away from the blocking sheet 17 is perpendicularly connected to the long vertical board 15. A horizontal slot 161 is defined in the short vertical board 16 and the blocking sheet 17, to reduce the weight of the main body 10. A connecting hole 171 is defined in the blocking sheet 17, for connecting the blocking sheet 17 to the fixing board 30. A vertical first slit 151 is defined in the short vertical board 16 at a joint of the long vertical board 15 and the short vertical board 16. A vertical second slit 152 is defined in a middle portion of the long vertical board 15. A transverse width of each of the first slit 151 and the second slit 152 is substantially equal to a thickness of a protruding end 32 of the fixing board 30. Thus, each of the first slit 151 and the second slit 152 can receive the protruding end 32 of the fixing board 30 therein, if and as required. In the present embodiment, the first slit 151 receives the protruding end 32 of the fixing board 30 therein. A plurality of connecting holes 153 is defined in the long vertical board 15.

The two interface converters 20 are fixed to the long vertical board 15 through the connecting holes 153. One interface converter 20 is fixed to part of the long vertical board 15 between the first short board 12 and the second short board 13, and the other interface converter 20 is fixed to another part of the long vertical board 15 between the second short board 13 and the third short board 14. When received in the bracing structure 100, the FH/FL card 200 can be connected to either one of the interface converters 20 according to a position of the connecting foot 202 of the FH/FL card 200. Each interface converter 20 includes a card slot 21 and a card strip 22. An opening of the card slot 21 faces away from the long vertical board 15, and is substantially parallel to a surface of the long board 11. The connecting foot 202 of the FH/FL card 200 is inserted into the card slot 21 via the opening. The card strip 22 is substantially vertical to the card slot 21. A height of the card strip 22 is bigger than that of the long vertical board 15, so that the FH/FL card 200 can electrically connect to other components (not shown) via gold fingers (not labeled) arranged at a top of the card strip 22.

The fixing board 30 is fixed on the short vertical board 16 at the fixing end 18 of the main body 10, to fix the first end of the FH/FL card 200 to the bracing structure 100. The fixing board 30 has substantially a long strip shaped construction, and has a transverse width (i.e. height) equal to that of the short vertical board 16. The fixing board 30 includes a bent plate 31 positioned at an end thereof, the protruding end 32 positioned at the other end thereof, and a pair of intermediate, spaced connecting pieces 33.

A connecting cutout 311 is defined in the bent plate 31. The connecting cutout 311 enables a screw (not labeled) to be used to secure the bent plate 31 on the blocking sheet 17, thereby limiting movement of the fixing board 30 along directions perpendicular to the lengthwise direction of the long board 11. A height of the protruding end 32 is substantially equal to a height of the first slit 151 (and the second slit 152). Accordingly, the protruding end 32 can be received in the first slit 151, and movement of the protruding end 32 can be limited because of the substantially equal height of the protruding end 32 and the first slit 151. Thereby, not only is movement of the fixing board 30 along the lengthwise direction of the long board 11 limited, but also movement of the fixing board 30 in vertical directions is limited. Each of the connecting pieces 33 extends from a bottom side of a main body of the fixing board 30, in a direction opposite to a direction in which the bent plate 31 extends from the main body of the fixing board 30. Each connecting piece 33 has a connecting hole 331 defined therein. The two connecting holes 331 correspond to two of the mounting holes 201 of the FH/FL card 200 which are at the first end of the FH/FL card 200, and enable the first end of the FH/FL card 200 to be secured to the fixing board 30 by screwing.

The fixing frame 40 is mounted on the third short board 14, for securing an opposite second end of the FH/FL card 200 which is far away from the short vertical board 16. The fixing frame 40 includes at least four side plates. In the illustrated embodiment, there are a securing plate 41, a fixing plate 42 vertically connected to the securing plate 41, and two connecting plates 43 connected to the securing plate 41 and the fixing plate 42 respectively. The securing plate 41 can be fixed on the third short board 14 by screws (not labeled), which are extended through the connecting holes 141 of the third short board 14 and engaged with the securing plate 41. A plurality of through holes 421 are defined in the fixing plate 42, for connecting the guiding element 50 to the fixing plate 42. A plurality of connecting holes 431 are defined in the connecting plates 43. A screw (not shown) can be passed through the connecting hole 431 of one of the connecting plates 43, to connect that connecting plate 43 to the long vertical board 15 of the main body 10.

The guiding element 50 is employed to assist securing of the second end of the FH/FL card 200 to the bracing structure 100. The guiding element 50 includes two major surfaces at opposite sides thereof. A pair of mushroom-shaped elastic fixing posts 51 is formed on one of the side surfaces of the guiding element 50, and a longitudinal guiding slot 52 is defined in the other side surface of the guiding element 50. In addition, a U-shaped locking clip 53 is attachable to an end of the guiding element 50. Each elastic fixing post 51 includes a bifurcated, generally mushroom-shaped head, which can be deformed radially inwardly. Thus the elastic fixing post 51 can be deformably and detachably engaged in a corresponding through hole 421 of the fixing frame 40, thereby fixing the guiding element 50 on the fixing frame 40. The guiding slot 52 extends along a direction perpendicular to the lengthwise direction of the long board 11. Thereby, the FH/FL card 200 can be easily inserted into the main body 10, with the second end of the FH/FL card 200 sliding along the guiding slot 52. When the locking clip 53 is attached to the guiding element 50, the locking clip 53 blocks an entrance end of the guiding slot 52, and thus can prevent the second end of the inserted FH/FL card 200 from moving back away from the long board 11.

When the FH/FL card 200 is assembled to the bracing structure 100, the fixing board 30 fixed on the first end of the FH/FL card 200 is positioned adjacent to the fixing end 18, and the second end of the FH/FL card 200 is positioned adjacent to the fixing frame 40. The FH/FL card 200 is slid toward the long vertical board 15, with the second end of the FH/FL card 200 sliding along the guiding slot 52 of the guiding element 50, until the connecting foot 202 of the FH/FL card 200 is inserted into and engaged with the card slot 21 of the corresponding interface converter 20. In this position, the bent plate 31 of the fixing board 30 abuts against the blocking sheet 17 of the main body 10, with the connecting cutout 311 and the connecting hole 171 aligned with each other, and the protruding end 32 of the fixing board 30 is received in the first slit 151 of the short vertical board 16. A corresponding screw (not labeled) is passed through the connecting cutout 311 and the connecting hole 171, to fix the first end of the FH/FL card 200 to the bracing structure 100. The locking clip 53 is attached to the guiding element 50, and prevents the second end of the FH/FL card 200 from moving back away from the long board 11. As such, the two ends of the FH/FL card 200 are fixed to the bracing structure 100, and the FH/FL card 200 is ready for a next stage in an assembly process such as an impact test.

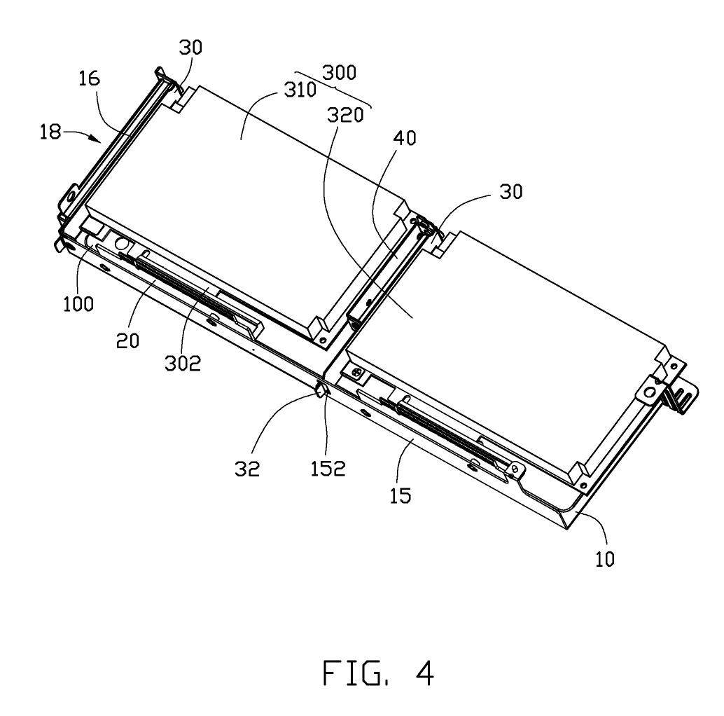

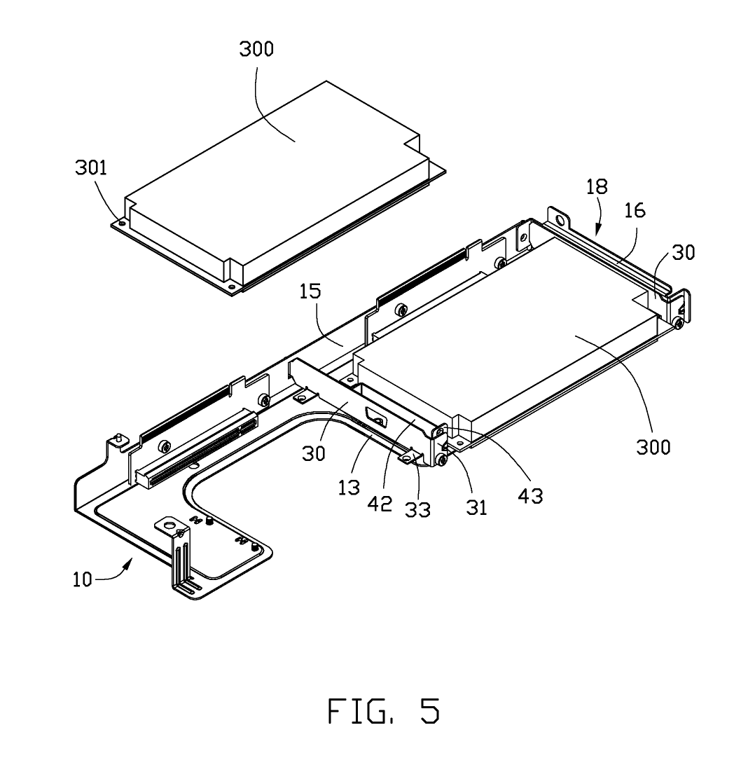

Referring to FIGS. 4 and 5, these show the bracing structure 100 used to secure two FH/HL cards 300, in accordance with a second embodiment. In this embodiment, two fixing boards 30 are employed to assist the bracing structure 100 in securing the FH/HL cards 300, respectively, the fixing frame 40 is fixed at a middle of the bracing structure 100 and distant from the long vertical board 15, and the guiding element 50 (of the first embodiment) is omitted. The two FH/HL cards 300 are a first FH/HL card 310 and a second FH/HL card 320. Each FH/HL card 300 has substantially a rectangular construction. Four fixing holes 301 are defined at four corners of each FH/HL card 300, and a connecting foot 302 extends from a long lateral side of the FH/HL card 300. A width of the FH/HL card 300 is substantially equal to that of the FH/FL card 200 (of the first embodiment), and a length of the FH/HL card 300 is substantially half of that of the FH/FL card 200. A respective one of the fixing boards 30 is fixed on a short side (hereinafter, “first end”) of each FH/HL card 300. That is, each fixing board 30 extends along a widthwise direction of the corresponding FH/HL card 300. A first one of the fixing boards 30 is fixed at the fixing end 18 of the main body 10 for securing a first end of the first FH/HL card 310. The second fixing board 30 is fixed at a middle portion of the main body 10 for securing a first end of the second FH/HL card 320.

The first end of the first FH/HL card 310 is fixed to the bracing structure 100 in the same way as the first end of the FH/FL card 200 (of the first embodiment). The first end of the second FH/HL card 320 is fixed by the second fixing board 30 and the fixing frame 40. The fixing frame 40 is mounted on the second short board 13. The fixing plate 42 of the fixing frame 40 is adjacent to an opposite second end of the first FH/HL card 310, and one of the connecting plates 43 is adjacent to an end of the second short board 13 far away from the long vertical board 15. The second fixing board 30 is fixed on a side of the fixing frame 40 opposite to the side having the fixing plate 42. Detailedly, the bent plate 31 of the second fixing board 30 is attached to the corresponding connecting plate 43, the protruding end 32 of the second fixing board 30 is received in the second slit 152, and the connecting pieces 33 of the second fixing board 30 extend in a direction away from the fixing end 18.

When the two FH/HL cards 300 are assembled to the bracing structure 100, the fixing frame 40 is firstly fixed on the second short board 13 by screws (not shown in FIGS. 4-5), which are extended through corresponding connecting holes 131 of the second short board 13 and engaged with the securing plate 41. The two FH/HL cards 300 are inserted into the two card slots 21 of the two interface converters 20, respectively, with the connecting feet 302 of the FH/HL cards 300 engaging in the card slots 21. The first FH/HL card 310 is positioned spanning from the first short board 12 to the second short board 13. The second FH/HL card 320 is positioned spanning from the second short board 13 to the third short board 14. Finally, the bent plate 31 of the first fixing board 30 abuts against the blocking sheet 17 of the main body 10 and is secured in position by a screw (not labeled); and the bent plate 31 of the second fixing board 30 abuts against the corresponding connecting plate 43 of the fixing frame 40 and is secured in position by a screw (not labeled). Thereby, the first ends of the FH/HL cards 300 are secured to the bracing structure 100. Because of the half length of the FH/HL cards 300, unlike with the FH/FL card 200 of the first embodiment, the assembly of the bracing structure 100 and the FH/HL cards 300 does not require that the second ends of the FH/HL cards 300 be secured before a next stage in an assembly process. The assembly of the bracing structure 100 and the FH/HL cards 300 is ready for the next stage, such as an impact test.

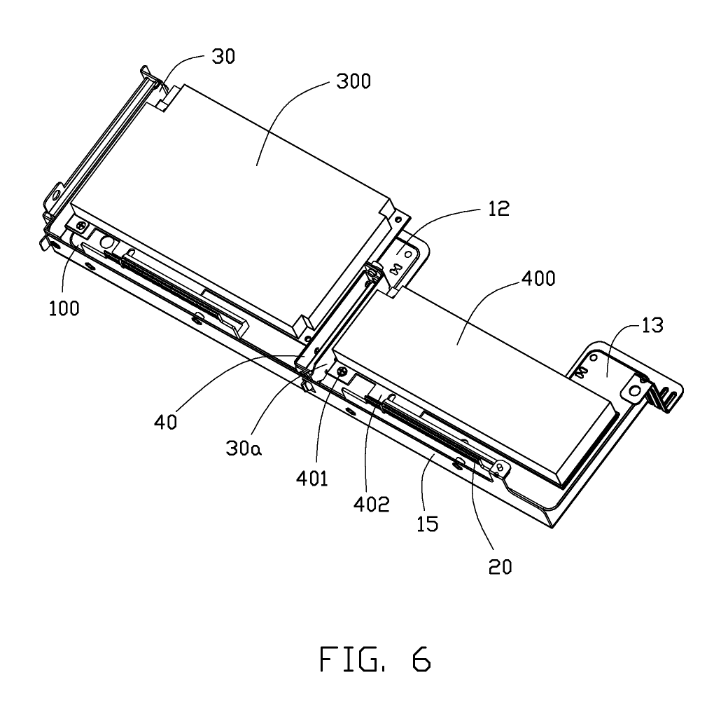

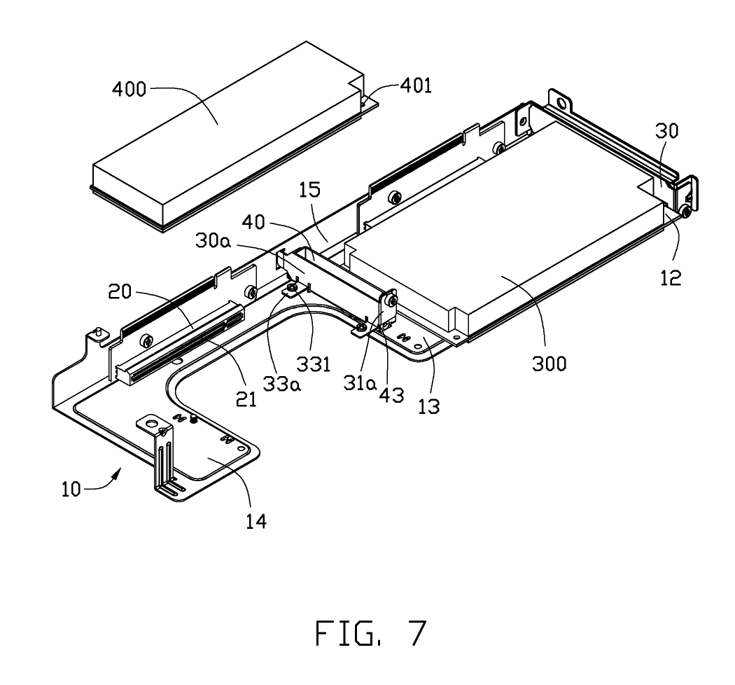

Referring to FIGS. 6 and 7, these show the bracing structure 100 used to secure one FH/HL card 300 and an LP card 400, in accordance with a third embodiment. In this embodiment, one fixing board 30 and another fixing board 30a are employed to assist the bracing structure 100 in securing the FH/HL card 300 and the LP card 400, respectively, the fixing frame 40 is fixed at a middle of the bracing structure 100 and adjacent to the long vertical board 15, and the guiding element 50 (of the first embodiment) is omitted. The fixing board 30a has a shape and construction similar to the fixing board 30. The main differences between the two fixing boards 30, 30a are that a length of the fixing board 30a is smaller than that of the fixing board 30; correspondingly, a pair of connecting pieces 33a of the fixing board 30a are closer to each other than are the connecting pieces 33 of the fixing board 30; and a bent plate 31a of the fixing board 30a has a different configuration from the bent plate 31 of the fixing board 30.

The LP card 400 has substantially a rectangular construction. Four fixing holes 401 are defined at four corners of the LP card 400, and a connecting foot 402 extends from a long lateral side of the LP card 400. A width of the LP card 400 is substantially smaller than that of the FH/HL card 300, and a length of the LP card 400 is substantially equal to that of the FH/HL card 300. The length of the fixing board 30a is substantially equal to the width of the LP card 400. The fixing board 30a is fixed on a short side (hereinafter, “first end”) of the LP card 400. That is, the fixing board 30a extends along a widthwise direction of the LP card 400. The fixing board 30a is fixed at a middle portion of the main body 10 for securing the first end of the LP card 400.

The first end of the FH/HL card 300 is fixed to the bracing structure 100 in the same way as the first end of the first FH/HL card 310 (of the second embodiment). Compared with the fixing position of the fixing frame 40 in the second embodiment, the fixing frame 40 has been moved towards the long vertical board 15 along a direction parallel to the second short board 12 to be fixed adjacent to the long vertical board 15. The first end of the LP card 400 is fixed to the bracing structure 100 in much the same way as the first end of the second FH/HL card 320 (of the second embodiment).

When the FH/HL card 300 and the LP card 400 are assembled to the bracing structure 100, the fixing frame 40 is firstly fixed on the second short board 13 adjacent to the long vertical board 15. The FH/HL card 300 and the LP card 400 are inserted into the two card slots 21 of the two interface converters 20, respectively. The FH/HL card 300 is positioned spanning from the first short board 12 to the second short board 13, in the same way as the first FH/HL card 310 of the second embodiment. The LP card 400 is positioned spanning from the second short board 13 to the third short board 14. Finally, the bent plate 31 of the fixing board 30 abuts against the blocking sheet 17 of the main body 10 and is secured in position by a screw (not labeled), for securing the FH/HL card 300; and the bent plate 31a of the fixing board 30a abuts against the corresponding connecting plate 43 of the fixing frame 40 and is secured in position by a screw (not labeled). Thereby, the first ends of the FH/HL card 300 and LP card 400 are secured to the bracing structure 100. Because of the half length of the FH/HL card 300 and LP card 400, unlike with the FH/FL card 200 of the first embodiment, the assembly of the bracing structure 100 and the FH/HL card 300 and LP card 400 does not require that the second ends of the FH/HL card 300 and LP card 400 be secured before a next stage in an assembly process. The assembly of the bracing structure 100 and the FH/HL card 300 and LP card 400 is ready for the next stage, such as an impact test.

In summary, the main body 10 includes the three short boards 12, 13, 14, and the fixing frame 40 capable of being fixed at three different positions on the second and third short boards 13, 14 according to the different sizes of the expansion cards. When the FH/FL card 200 is assembled to the bracing structure 100, the fixing frame 40 is located on the third short board 14, to provide sufficient mounting space for the FH/FL card 200. In addition, the FH/FL card 200 is held in the guiding slot 52 of the guiding element 50 to strengthen the stability of the assembly of the bracing structure 100 and the FH/FL card 200. When two FH/HL cards 300 are assembled to the bracing structure 100, the fixing frame 40 is fixed on the second short board 12 in the middle portion of the bracing structure 100 and distant from the long vertical board 15, to define two mounting spaces. One of the mounting spaces spans from the first short board 12 to the second short board 13, and the other mounting space spans from the second short board 13 to the third short board 14, for receiving the two FH/HL cards 300. When the FH/HL card 300 and the LP card 400 are assembled to the bracing structure 100, the fixing frame 40 is fixed on the second short board 12 in the middle portion of the bracing structure 100 and adjacent to the long vertical board 15, to define two mounting spaces. The length of the fixing board 30a is equal to the width of the LP card 400, and the mounting spaces receive the FH/HL card 300 and the LP card 400.

The above-described configurations obviate the need for providing different bracing structures for differently sized expansion cards. Thereby, space inside an associated electronic device can be saved, the cost and time required to design such electronic devices can be reduced, and the cost and time required to manufacture such electronic devices can be reduced.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A bracing structure for selectively securing either one expansion card or two expansion cards, all the expansion cards selected from a group consisting of differently sized expansion cards, the bracing structure comprising:
a main body with a fixing end; and
a fixing frame configured for fixing one end of a selected one expansion card in position in the bracing structure, the fixing frame detachably fixable to a plurality of different positions on the main body according to said selected one expansion card, wherein in two of the different positions the fixing frame maintains different distances from the fixing end.

2. The bracing structure of claim 1, wherein the main body comprises a horizontal long board, three horizontal short boards and three vertical boards, the three short boards comprising a first short board, a second short board and a third short board, the second short board being located between the first short board and the third short board, the three short boards extending perpendicularly inward from a long inner edge of the long board to form an approximately E-shaped construction together with the long board, the three vertical boards comprising a long vertical board connected to the long board perpendicularly, a short vertical board connected to the first short board and an end of the long board perpendicularly, and a blocking sheet bent outward from an end of the short vertical board perpendicularly, the fixing end of the main body being cooperatively formed by the short vertical board and the blocking sheet, and the fixing frame being detachably fixable on a selected one of the second short board and the third short board.

3. The bracing structure of claim 2, wherein the fixing frame comprises a securing plate and a fixing plate perpendicular and adjacent to the securing plate, and when the bracing structure secures one expansion card, the fixing frame is fixed on the third short board via the securing plate, the fixing plate faces toward the short vertical board, a first end of the expansion card is fixed on the fixing end at the short vertical board, and an opposite second end of the expansion card is fixed on the third short board via the fixing frame.

4. The bracing structure of claim 3, further comprising a guiding element attached to the fixing plate, wherein the guiding element comprises two opposite side surfaces facing away from each other, an elastic fixing post is formed on one of the side surfaces of the guiding element, a guiding slot is defined in the other side surface of the guiding element to receive the second end of the expansion card, a through hole is defined in the fixing plate of the fixing frame, and the elastic fixing post is engaged in the through hole to attach the guiding element on the fixing frame.

5. The bracing structure of claim 2, wherein the fixing frame comprises a securing plate and a fixing plate perpendicular and adjacent to the securing plate, and when the bracing structure secures two expansion cards, the fixing frame is fixed on the second short board via the securing plate, the fixing plate faces toward the short vertical board, a first one of the expansion cards is positioned spanning from the first short board to the second short board, with one end of the first expansion card fixed on the fixing end at the short vertical board, and the second expansion card is positioned spanning from the second short board to the third short board, with one end of the second expansion card fixed on the second short board via the fixing frame.

6. The bracing structure of claim 5, wherein the fixing frame fixed on the second board is spaced a distance from the long vertical board when the two expansion cards have the same size.

7. The bracing structure of claim 6, further comprising two fixing boards, wherein a first one of the fixing boards is fixed on the end of the first expansion card, the end of the first expansion card is fixed on the fixing end via the first fixing board being fixed on the blocking sheet, the fixing frame further comprises a connecting plate connected perpendicularly with both the securing plate and the fixing plate at an end of the fixing frame far away from the long vertical board, the second fixing board is fixed on the end of the second expansion card, and the end of the second expansion card is fixed on the second short board via the second fixing board being fixed on the connecting plate of the fixing frame.

8. The bracing structure of claim 5, wherein the fixing frame fixed on the second board is adjacent to the long vertical board when the two expansion cards have different sizes.

9. The bracing structure of claim 8, further comprising two fixing boards, wherein a longer one of the fixing boards is fixed on the end of the first expansion card, the end of the first expansion card is fixed on the fixing end via the first fixing board being fixed on the blocking sheet, the fixing frame further comprises a connecting plate connected perpendicularly with both the securing plate and the fixing plate at an end of the fixing frame far away from the long vertical board, a shorter one of the fixing boards is fixed on the end of the second expansion card, and the end of the second expansion card is fixed on the second short board via the second fixing board being fixed on the connecting plate of the fixing frame.

10. The bracing structure of claim 2, wherein when the bracing structure secures one expansion card, the bracing structure further comprises a fixing board and the fixing frame is detachably fixed on the third short board, the fixing board comprises a board main body, a bent plate positioned at an end of the board main body, a protruding end positioned at an opposite end of the board main body, and a connecting piece extending from a bottom side of the board main body of the fixing board in a direction opposite to a direction in which the bent plate extends from the board main body, one end of the expansion card is fixed on the connecting piece, and the bent plate is fixed on the blocking sheet.

11. The bracing structure of claim 10, wherein the short vertical board has a first slit defined therein where the short vertical board abuts the long vertical board, and the protruding end of the fixing board is engaged in the first slit.

12. The bracing structure of claim 11, wherein the long vertical board has a second slit defined therein, the second slit being located in a middle portion of the long vertical board.

13. The bracing structure of claim 1, further comprising an interface converter fixed to the main body, wherein the interface converter comprises a card slot for receiving a part of a corresponding expansion card secured in the bracing structure and a card strip for electrically connecting the corresponding expansion card to other components outside the bracing structure.

14. The bracing structure of claim 2, further comprising two interface converters fixed to the long vertical board, wherein each interface converter comprises a card slot for receiving a part of a corresponding expansion card secured in the bracing structure and a card strip for electrically connecting the corresponding expansion card to other components outside the bracing structure.

15. A bracing structure for selectively securing either a long expansion card or two short expansion cards, the two short expansion cards selectively being either a pair of first short expansion cards or one of the first short expansion cards and a second short expansion card, the one of the first short expansion cards and the second short expansion card having different widths, the bracing structure comprising:
a main body comprising;
a long lateral side; and
a fixing end for fixing an end of the long expansion card or an end of one first short expansion card, as selected; and
a fixing frame detachably fixable to a plurality of different positions on the main body according to whether the long expansion card is selected or on condition that the two short expansion cards are selected according to which two short expansion cards are selected;
wherein the fixing frame maintains different distances from the fixing end according to whether the long expansion card is selected or the two short expansion cards are selected; and
when the two short expansion cards are selected, the fixing frame maintains different distances from the long lateral side according to whether the pair of first short expansion cards are selected or the one of the first short expansion cards and the second short expansion card are selected.

16. The bracing structure of claim 15, wherein the main body comprises a horizontal long board, three horizontal short boards and three vertical boards, the three short boards comprising a first short board, a second short board and a third short board, the second short board being located between the first short board and the third short board, the three short boards extending perpendicularly inward from a long inner edge of the long board to form an approximately E-shaped construction together with the long board, the three vertical boards comprising a long vertical board connected to the long board perpendicularly, a short vertical board connected to the first short board and an end of the long board perpendicularly, and a blocking sheet bent outward from an end of the short vertical board perpendicularly, the fixing end of the main body being cooperatively formed by the short vertical board and the blocking sheet, and the fixing frame being detachably fixable on a selected one of the second short board and the third short board.

17. The bracing structure of claim 16, wherein the fixing frame comprises a securing plate and a fixing plate perpendicular and adjacent to the securing plate, and when the bracing structure secures the long expansion card, the fixing frame is fixed on the third short board via the securing plate, the fixing plate faces toward the short vertical board, a first end of the long expansion card is fixed on the fixing end at the short vertical board, and an opposite second end of the long expansion card is fixed on the third short board via the fixing frame.

18. An electronic device comprising:
either one expansion card or two expansion cards, all the expansion cards selected from a group consisting of differently sized expansion cards, each of the expansion cards having a fixing board fixed on an end thereof; and
a bracing structure comprising:
a main body with a fixing end; and
a fixing frame configured for fixing one end of a selected one expansion card in position in the bracing structure, the fixing frame detachably fixable to a plurality of different positions on the main body according to said selected one expansion card, wherein in two of the different positions the fixing frame maintains different distances from the fixing end.

19. The electronic device of claim 18, wherein the fixing frame comprises a securing plate and a fixing plate perpendicular and adjacent to the securing plate, and when the bracing structure secures one expansion card, the fixing frame is fixed on the bracing structure by the securing plate, the fixing plate faces toward the fixing end, a first end of the expansion card is fixed on the fixing end of the main body, and an opposite second end of the expansion card is fixed on the main body via the fixing frame.
